(19) United States
(12) Patent Application Publication
(10) Pub. No.: US 2025/0161996 A1
(43) Pub. Date: May 22, 2025

(54) SUBSTRATE PROCESSING APPARATUS AND CHAMBER CLEANING METHOD

(71) Applicant: TES CO., LTD, Yongin-si (KR)

(72) Inventors: Tae-Yoon KIM, Yongin-si (KR); Woo-Young CHUNG, Yongin-si (KR); Jin-Young MIN, Yongin-si (KR); Kwang-Hoon JUNG, Yongin-si (KR)

(73) Assignee: TES CO., LTD, Yongin-si (KR)

(21) Appl. No.: 18/946,825

(22) Filed: Nov. 13, 2024

(30) Foreign Application Priority Data
Nov. 17, 2023 (KR) 10-2023-0159651

(51) Int. Cl. B08B 5/00; B08B 7/00

(52) U.S. Cl. CPC B08B 5/00; B08B 7/0071; B08B 2205/00

(57) ABSTRACT

A substrate processing apparatus includes a chamber, an upper heater, a substrate supporter, and a lower showerhead. The chamber provides a processing space in which a process for a substrate is performed. The upper heater is provided in an upper region of an interior of the chamber and is configured to supply purge gas and to heat the substrate. The substrate supporter is provided in a lower region of the interior of the chamber and is configured to support the substrate. The lower showerhead is provided in the substrate supporter and is configured to supply cleaning gas or remote plasma.

### CROSS-REFERENCE TO RELATED APPLICATIONS

A claim for priority under 35 U.S.C. § 119 is made to Korean Patent Application No. 10-2023-0159651 filed on Nov. 17, 2023, in the Korean Intellectual Property Office, the entire contents of which are hereby incorporated by reference.

### BACKGROUND OF THE INVENTION

### Field of the Invention

The present invention relates to an apparatus for processing a substrate and a method for cleaning a chamber, and more particularly to a substrate processing apparatus and a chamber cleaning method that can effectively clean an inside of the chamber even in a high temperature process.

### Description of the Related Art

In the prior art, a substrate processing apparatus deposits a thin film or a thin layer of a predetermined thickness on one side of a substrate, for example on a top surface of a substrate. In this case, when the thin films are deposited and superimposed on the top surface of the substrate, the stress of the thin films can cause the substrate to bow.

When the substrate is bowed in this manner, it becomes difficult to position the substrate in a correct position when the substrate is processed in various substrate processes that follow, and this bowing phenomenon reduces precision of the processes, especially while the precision of the substrate processes is increasing day by day. Therefore, to prevent the bowing phenomenon of the substrate described above, a thin film of a predetermined thickness is deposited on a bottom surface of the substrate.

Such a substrate processing apparatus is provided with an upper heater that supplies purge gas to a top portion of the substrate, and a lower showerhead that supplies process gas to a bottom portion of the substrate. In this configuration, for cleaning an inside or interior of the chamber, the conventional substrate processing apparatus supplied cleaning gas, for example, Nitrogen Trifluoride (NF₃) and the like in the form of remote plasma, through the upper heater made of Aluminum Nitrogen (AlN).

When the cleaning gas is supplied through the upper heater in this way, particle issues do not arise in the chamber that has undergone a low-temperature process below about 400° C. However, in the case of the chamber that has recently undergone a high temperature process of approximately 400° C. or higher, the upper heater made of AlN is subjected to a high temperature, and when NF₃ and the like are supplied, Aluminum Fluoride (AIF) and the like are generated inside the upper heater and particles become an issue.

To solve this problem, the substrate processing apparatus according to the prior art adopted a technology that supplies the cleaning gas along a side of the upper heater in an upper region of the chamber. However, this method had the problem that the cleaning gas is directly exhausted through an exhaust port at a lower regioin of the chamber and is not supplied to a center part of the upper heater or lower showerhead. As a result, a cleaning time for cleaning the center part of the upper heater or lower showerhead was extended, and moreover, a surface of the upper heater or lower showerhead was not uniformly cleaned.

In addition, in the prior art, in order to clean the inside or interior of the chamber, a temperature of the upper heater was reduced to less than 400° C. in the chamber subjected to the high temperature process of approximately 400° C. or higher, to prevent the generation of AIF and the like in the upper heater. However, such a method required a time to proceed with a cleaning process by lowering the temperature of the upper heater, and then to raise the temperature of the upper heater again to a process temperature, i.e., a temperature of approximately 400° C. or higher, which significantly reduced a throughput of the substrate processing apparatus.

### SUMMARY OF THE INVENTION

The present invention is contemplated to solve problems in the prior art mentioned above. Thus, an object of the present invention is to provide a substrate processing apparatus and a chamber cleaning method that can effectively clean a surface of an upper heater or a lower showerhead inside a chamber even in a high temperature process.

Further, it is an object of the present invention to provide a substrate processing apparatus and a chamber cleaning method that do not require lowering a temperature of the upper heater even when a cleaning process is performed between successive and repetitive high temperature deposition processes for depositing a thin film or a thin layer on a bottom surface of a substrate.

To solve the above problems, according to a first aspect of the invention, the present invention may provide a substrate processing apparatus comprising: a chamber providing a processing space in which a process for a substrate is performed; an upper heater provided in an upper region of an interior of the chamber, the upper heater being configured to supply purge gas and to heat the substrate; a substrate supporter provided in a lower region of the interior of the chamber and configured to support the substrate; and a lower showerhead provided in the substrate supporter and configured to supply cleaning gas or remote plasma.

Here, the upper heater and the lower showerhead may be configured to be movable relative to each other.

Further, the lower showerhead may be configured to move up and down, and a remote plasma source (RPS) may be configured to move up and down together with the lower showerhead.

Meanwhile, the upper heater may be configured to move up and down, and the upper heater may be configured to move upwardly when the interior of the chamber is cleaned.

In addition, the substrate processing apparatus may further comprise an additional supply channel for supplying the purge gas through an upper edge of the chamber. Meanwhile, according to a second aspect of the invention, the present invention may provide a chamber cleaning method, the method being performed to clean a chamber between successive and repetitive deposition processes for depositing a thin film on a bottom surface of a substrate, comprising: maintaining a process temperature of the deposition process; supplying purge gas through an upper heater provided in an upper region of an interior of the chamber; and cleaning the interior of the chamber by providing cleaning gas or remote plasma through a lower showerhead located in a lower region of the interior of the chamber.

Here, the process temperature may be a temperature at or above which the cleaning gas reacts with the upper heater to generate a reaction byproduct.

For example, the process temperature may be 400° C. or higher.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is a side sectional view of the substrate processing apparatus according to FIG. 1 illustrating a state in which purge gas or cleaning gas is supplied; and

FIGS. 3A and 3B are block diagrams comparing a sequence of a chamber cleaning process according to the prior art and a sequence of a chamber cleaning process according to the present invention.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, the structure of the substrate processing apparatus 1000 according to an embodiment of the present invention will be described in detail with reference to the accompanying drawings.

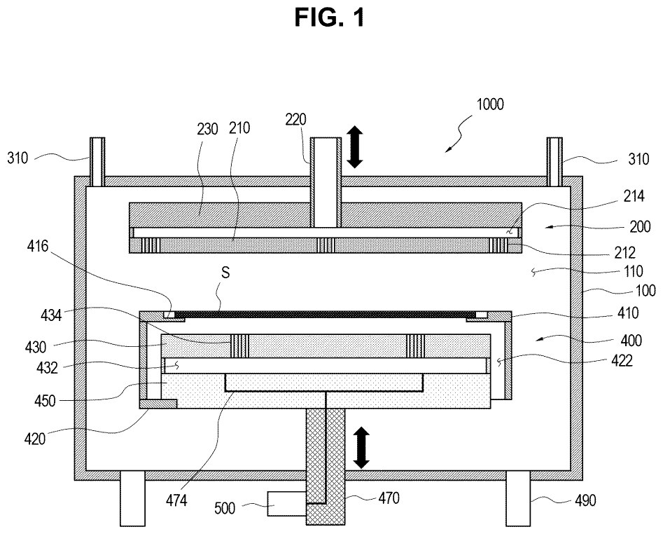

FIG. 1 is a side sectional view of a substrate processing apparatus 1000 according to one embodiment of the present invention.

Referring to FIG. 1, the substrate processing apparatus 1000 may include a chamber 100 providing a processing space 110 in which a process for a substrate S is performed, an upper heater 200 provided in an upper region of an inside or interior of the chamber 100 to supply purge gas and to heat the substrate S, a substrate supporter 400 provided in a lower region of the inside or the interior of the chamber 100 to support the substrate S, and a lower showerhead 430 provided in an inside or interior of the substrate supporter 400 to supply cleaning gas or remote plasma.

Specifically, the chamber 100 may provide the processing space 110 in which various components necessary for the deposition process on the substrate S are housed.

Any one side of the chamber 100 may be provided with an opening (not shown) through which the substrate S is loaded into the processing space 110 or unloaded from the processing space 110, and a door (not shown) may be provided to the opening.

The upper region of the chamber 100 may be provided with the upper heater 200 for supplying the purge gas, such as inert gas, towards a top surface of the substrate S.

Meanwhile, an upper part of the chamber 100 may be connected with an upper supply channel 220 through which the purge gas is supplied.

The purge gas supplied along the upper supply channel 220 is fed downward through the upper heater 200.

The purge gas supplied from the upper heater 200 is supplied toward the processing space 110 below and prevents the cleaning gas or the remote plasma supplied from the lower showerhead 430 from being in contact with the upper heater 200.

Specifically, the upper heater 200 may include a heater plate 230 and a showerhead plate 210 provided on a lower part of the heater plate 230. A first buffer space 214 may be provided between the heater plate 230 and the showerhead plate 210.

The heater plate 230 may include a heater (not shown) provided therein to heat the substrate S and the processing space 110 to a predetermined process temperature.

Meanwhile, a plurality of first supply holes 212 may be formed at the showerhead plate 210.

Accordingly, the purge gas supplied via the upper supply channel 220 diffuses in the first buffer space 214 and is supplied downward via the first supply holes 212 of the showerhead plate 210. In FIG. 1, the first supply holes 212 are shown as being formed in only a portion of the showerhead plate 210 for illustrative convenience, but the first supply holes 212 may be formed across the entirety of the showerhead plate 210.

Meanwhile, the upper heater 200 and the lower showerhead 430 may be provided to be movable relative to each other. In this case, as the lower showerhead 430 moves along with the substrate supporter 400, such configuration corresponds to a structure in which the upper heater 200 and the substrate supporter 400 are provided to be relatively movable to each other.

Although FIG. 1 illustrates a structure in which both of the upper heater 200 and the lower substrate supporter 400 are movable up and down as shown by arrows, the configuration of the heater 200 and the supporter 400 is not limited thereto, and at least one of the upper heater 200 and the substrate supporter 400 may be configured to be movable up and down.

For example, the substrate supporter 400 may be movably provided up and down in a lower region of the processing space 110, and may support a bottom edge of the substrate S. The inside or interior of the substrate supporter 400 may be provided with the lower showerhead 430, and the cleaning gas or remote plasma may be supplied by the lower showerhead 430.

The substrate supporter 400 is connected to a shaft 470 extending downwardly, and the shaft 470 is connected with a driving unit (not shown) such as a motor or the like, such that the shaft 470, the substrate supporter 400, and the lower showerhead 430 may be moved up and down by operating the drive unit.

Meanwhile, when the upper heater 200 is movable up and down and the substrate supporter 400 is stationary or fixed, the upper heater 200 may be moved upward in the case of cleaning the interior of the chamber 100. Thereby, the distance between the lower showerhead 430 and the upper heater 200 may be increased to prevent particle generation on the upper heater 200 during the cleaning process.

Meanwhile, the substrate supporter 400 may include a substrate holder 410 supporting an edge of the bottom surface of the substrate S, and may include the lower showerhead 430 described above inside the substrate holder 410. In addition, the substrate supporter 400 may further include a lower plate 450 at which a heat exchange channel (not shown) is formed.

In this case, the substrate supporter 410 may be supported by a fixture 420 of which a lower end is connected to the lower plate 450.

The substrate holder 410 may extend upwardly from the fixture 420, and may have a top end thereof bent inwardly.

In this case, a recess 416 may be formed at the top end of the substrate holder 410. Thus, when the substrate S is seated at the substrate holder 410, the substrate may be inserted into the recess 416 to support the bottom surface of the edge of the substrate.

Meanwhile, the cleaning gas or remote plasma may be supplied to the lower showerhead 430 via a lower supply line 474 which passes through the shaft 470.

The lower showerhead 430 may be provided with a second buffer space 432, and the second buffer space 432 may be located between the lower showerhead 430 and the bottom plate 450. Alternatively, although not shown in the drawings, the second buffer space 432 may be provided within the lower showerhead 430. Although not shown in the drawings, a baffle or blocking plate for dispersion of gases may be inserted between the lower showerhead 430 and the lower plate 450 or may be inserted in the buffer space 432.

As described above, when the substrate supporter 400 and the lower showerhead 430 are configured to be movable up and down, and when the remote plasma is provided to the lower showerhead 430, a remote plasma source (RPS) should be connected to a lower part of the lower showerhead 430 via a flexible or extensible member such as a bellows for up and down movement of the lower showerhead 430. However, such a bellows structure is generally made of Aluminum (Al) material or the like, which has the disadvantage of being vulnerable to corrosion by cleaning gas.

Therefore, in the present invention, when the lower showerhead 430 is configured to be movable up and down as shown in FIG. 1, the RPS 500 may be configured to be movable up and down together in conjunction with the lower showerhead 430.

In this case, the RPS 500 may be connected to the shaft 470 as shown in the drawings, but is not limited to such a location, and may be provided at any location where the RPS 500 is movable together in association with the lower showerhead 430.

Meanwhile, the heat exchange channel (not shown) may be formed at the lower plate 450, such that a heat exchange fluid or the like can flow along the heat exchange channel to regulate a temperature inside the chamber 100 or a temperature of the process gas through heat exchange. Therefore, since a lower part of the substrate supporter 400 can be maintained at a constant temperature, for example, about 70° C. to 80° C., by the heat exchange channel of the lower plate 450, temperature control becomes available even when the RPS 500 is arranged to move in conjunction with the lower showerhead 430 as described above.

Further, the lower plate 450 may serve to support the lower showerhead 430 and the substrate holder 410. In this case, the lower showerhead 430 may be connected to an upper surface of the lower plate 450. Further, the fixture 420, which supports a bottom end of the substrate holder 410, may be connected to the lower plate 450.

Here, a plurality of fixtures 420 may be provided and spaced apart at predetermined intervals along an outer circumference of the lower plate 450. That is, in the case of a plurality of fixtures 420, spaces between neighboring fixtures 420 may be open and communicate with the interior of the chamber 100. Thus, a space between sides of the lower showerhead 430 and the lower plate 450 and an inner surface of the substrate holder 410 may form an exhaust channel 422.

In this case, a portion of the process gas supplied from the lower showerhead 430 is discharged to the lower region of the interior of the chamber 100 through the exhaust channel 422, and then is exhausted to an outside of the chamber 100 through an exhaust port 490 provided at the lower part of the chamber 100.

Meanwhile, the purge gas supplied downwardly from the upper heater 200 may flow into the lower region of the chamber 100 and may be exhausted to the outside of the chamber 100 through the exhaust port 490.

Meanwhile, the substrate processing apparatus 1000 may further include an additional supply channel 310 for supplying the purge gas through an edge of the upper part of the chamber 100.

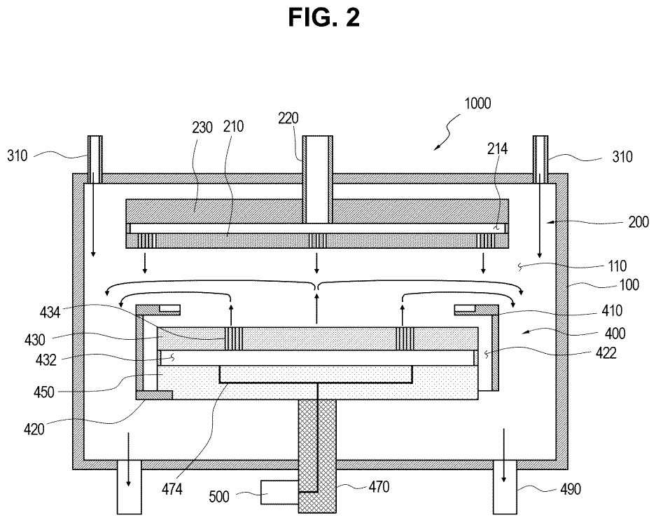

FIG. 2 illustrates the gases supplied through the additional supply channel 310, the upper heater 200, and the lower showerhead 430 during the cleaning process for the chamber 100, as indicated by arrows.

Referring to FIGS. 1 and 2, the additional supply channel 310 may be provided at an upper edge of the chamber 100. For example, when a chamber lid (not shown) is installed at the upper part of the chamber 100, the additional supply channel 310 may be provided at an edge of the chamber lid. A plurality of additional supply channels 310 may be provided along the upper edge of the chamber 100.

In the cleaning process of the chamber 100, the purge gas comprising the inert gas or the like may be supplied through the additional supply channel 310.

Further, in the cleaning process of the chamber 100, the purge gas may be supplied through the upper heater 200.

By the purge gas supplied through the upper heater 200 and the additional supply channel 310, the cleaning gas supplied from the lower showerhead 430 may be prevented from entering into the upper heater 200 and acting as particles. In particular, in a high temperature process of approximately 400° C. or higher, the remote plasma such as Nitrogen Trifluoride (NF₃) may be prevented from forming Aluminum Fluoride (AIF) in the upper heater 200 made of Aluminum Nitride (AlN) and acting as particles.

The purge gas supplied via the upper heater 200 and the additional supply channel 310 may be exhausted to the outside of the chamber 100 via the exhaust port 490 provided at the lower part of the chamber 100.

Meanwhile, during the cleaning process of the chamber 100, the remote plasma of NF₃ may be supplied through the lower showerhead 430.

By such remote plasma, contaminants such as particles or deposits on the surface of the lower showerhead 430 may be effectively removed.

Consequently, in the cleaning process of the chamber 100, the remote plasma may be supplied through the lower showerhead 430, and the purge gas may be supplied through the upper heater 200 and the additional supply channel 310.

Meanwhile, the substrate processing apparatus as described above repeats a high temperature deposition process for depositing a thin film or a thin layer on a bottom surface of the substrate S, and conducts the chamber cleaning process between the successive deposition processes.

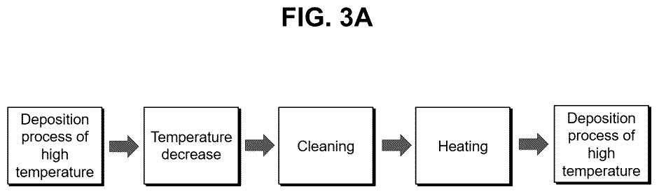

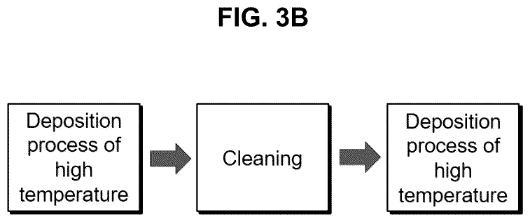

FIGS. 3A and 3B are block diagrams comparing sequences of a chamber cleaning process according to the prior art and a chamber cleaning process according to the present invention. The block diagram according to FIG. 3A illustrates the chamber cleaning process according to the prior art, and the block diagram according to FIG. 3B illustrates the chamber cleaning process according to the present invention.

As shown in FIG. 3A, the chamber cleaning process according to the prior art performs a step of lowering or decreasing the temperature inside the chamber 100 or the temperature of the upper heater 200 to the process temperature or below, after the deposition process having a high process temperature and depositing the thin film or layer on the bottom surface of the substrate S. This is to prevent AIF and the like from being generated at the upper heater 200. Here, the process temperature as mentioned above may be defined as a temperature at or above which the cleaning gas such as NF₃ reacts with the upper heater 200 to generate a reaction byproduct such as AIF. For example, the process temperature may correspond to a high temperature of approximately 400° C. or higher.

Subsequently, the cleaning step is performed, the temperature inside chamber 100 or the temperature of the upper heater 200 is increased again to the high temperature of 400° C. or higher, and then the thin film is again deposited on the bottom surface of the substrate S.

However, such a method requires a time to lower the temperature of the upper heater 200 to carry out the cleaning process, and to raise the temperature of the upper heater again to the process temperature, i.e., the temperature of approximately 400° C. or higher, which significantly reduces the throughput of the substrate processing apparatus.

In contrast, the chamber cleaning method according to the present invention does not require the step of lowering or re-raising the temperature inside the chamber 100 or the temperature of the upper heater 200 as shown in FIG. 3B, and the cleaning step can be carried out directly at the process temperature of the deposition process for depositing the thin film or layer on the bottom surface of the substrate S, which can significantly increase the throughput of the substrate processing apparatus.

For example, the chamber cleaning method according to the present invention may include a step of maintaining the process temperature of the deposition process for depositing the thin film or layer on the bottom surface of the substrate S, a step of supplying the purge gas through the upper heater 200 provided at the upper region of the interior or inside of the chamber 100, and a step of cleaning the interior or inside of the chamber 100 by providing the cleaning gas or remoting plasma through the lower showerhead 430 located in the lower region of the interior or inside of the chamber 100.

In other words, in the chamber cleaning method according to the present invention, the purge gas supplied through the upper heater 200 may prevent the remote plasma supplied by the lower showerhead 430 from entering into the upper heater 200 and acting as particles, so that it becomes unnecessary to lower or decrease the temperature of the upper heater 200. Particularly, in the high temperature process of about 400° C. or higher, the remote plasma such as NF₃ may be prevented from forming AIF in the upper heater 200 made of AlN and acting as particles.

The substrate processing apparatus and the chamber cleaning method according to the present invention have the technical advantages as follows.

According to the present invention with the configuration as described above, the center part of the upper heater or the lower showerhead can be effectively cleaned by providing the remote plasma through the lower showerhead.

Further, according to the present invention, when the remote plasma is provided through the lower showerhead, the purge gas is supplied through the upper heater. Therefore, it is not required to lower the high temperature of the heated upper heater, and thus the throughput of the substrate processing apparatus can be maintained.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber providing a processing space in which a process for a substrate is performed;
an upper heater provided in an upper region of an interior of the chamber, the upper heater being configured to supply purge gas and to heat the substrate;
a substrate supporter provided in a lower region of the interior of the chamber and configured to support the substrate; and
a lower showerhead provided in the substrate supporter and configured to supply cleaning gas or remote plasma.

2. The substrate processing apparatus of claim 1, wherein the upper heater and the lower showerhead are configured to be movable relative to each other.

3. The substrate processing apparatus of claim 2, wherein the lower showerhead is configured to move up and down, and a remote plasma source (RPS) is configured to move up and down together with the lower showerhead.

4. The substrate processing apparatus of claim 2, wherein the upper heater is configured to move up and down, and the upper heater is configured to move upwardly when the interior of the chamber is cleaned.

5. The substrate processing apparatus of claim 1, further comprising an additional supply channel for supplying the purge gas through an upper edge of the chamber.

6. A chamber cleaning method, the method being performed to clean a chamber for depositing a thin film on a bottom surface of a substrate during a deposition process, comprising:
maintaining a process temperature of the deposition process;
supplying purge gas through an upper heater provided in an upper region of an interior of the chamber; and
cleaning the interior of the chamber by providing cleaning gas or remote plasma through a lower showerhead located in a lower region of the interior of the chamber.

7. The chamber cleaning method of claim 6, wherein the process temperature is a temperature at or above which the cleaning gas reacts with the upper heater to generate a reaction byproduct.

8. The chamber cleaning method of claim 7, wherein the process temperature is 400° C. or higher.
